(19) United States
(12) Patent Application Publication
(10) Pub. No.: US 2026/0107596 A1
(43) Pub. Date: Apr. 16, 2026

(54) IMAGE SENSOR

(71) Applicant: Commissariat à I'Énergie Atomique et aux Énergies Alternatives, Paris (FR)

(72) Inventors: Sébastien Becker, Grenoble (FR); Abdelkader Aliane, Grenoble (FR); Quentin Abadie, Grenoble Cedex 9 (FR)

(73) Assignee: Commissariat à I'Énergie Atomique et aux Énergies Alternatives, Paris (FR)

(21) Appl. No.: 19/346,779

(22) Filed: Oct. 1, 2025

(30) Foreign Application Priority Data
Oct. 11, 2024 (FR) FR2411017

(51) Int. Cl. H10F 39/00

(52) U.S. Cl. CPC H10F 39/8067

(57) ABSTRACT

An image sensor including a plurality of pixels formed inside and on top of a semiconductor substrate and each including at least one photodetector including a resonant cavity including, between first and second mirror layers, a photoconversion layer and at least one diffractive structure.

### CROSS REFERENCE TO RELATED APPLICATIONS

This application claims priority to French application number FR2411017, filed Oct. 11, 2024. The contents of this application is incorporated by reference in its entirety.

### TECHNICAL FIELD

The present disclosure generally concerns electronic devices, more particularly image sensors comprising resonant-cavity-enhanced photodetectors.

### PRIOR ART

Image sensors comprising resonant-cavity-enhanced (RCE) photodetectors have been provided. Examples of such sensors, which enable to achieve a very good spectral selectivity, are for example detailed in the MDPI review by Jinzhao Li et al. entitled “Metasurface Photodetectors”. This review describes image sensors comprising photodetectors with resonant optical cavities of different thicknesses. The control of the thickness of each cavity is, in this case, performed by grayscale-type lithography. The image sensor thus obtained however has a number of spectral channels limited by a thickness resolution achievable by grayscale lithography. Further, the above-mentioned review indicates that other types of photodetectors with a resonant optical cavity have been provided to achieve a multispectral function. However, all the described provisions result in solutions technologically complex to implement because they comprise, in particular, structures suspended above air cavities.

### SUMMARY OF THE INVENTION

An object of an embodiment is to overcome all or part of the disadvantages of known image sensors and of their manufacturing methods. An embodiment aims in particular at overcoming all or part of the disadvantages of existing image sensors comprising photodetectors with a resonant optical cavity and methods of manufacturing such sensors.

For this purpose, an embodiment provides an image sensor comprising a plurality of pixels formed inside and on top of a semiconductor substrate and each comprising at least one photodetector comprising a resonant cavity comprising, between first and second mirror layers, a photoconversion layer and at least one diffractive structure.

According to an embodiment, each diffractive structure comprises a plurality of first regions made of a first material having a first refractive index separated from one another by at least one second region made of a second material having a second refractive index lower than the first refractive index.

According to an embodiment, the first and second materials have a same chemical composition and different structures.

According to an embodiment, the diffractive structures of the resonant cavities of the photodetectors have a same fill factor.

According to an embodiment, the at least one diffractive structure of the resonant cavity of one of the photodetectors has a fill factor different from that of the at least one diffractive structure of the resonant cavity of another photodetector.

According to an embodiment, the first regions of the at least one diffractive structure of the resonant cavity of one of the photodetectors form a grating having a pitch different from that of a grating formed by the first regions of the at least one diffractive structure of the resonant cavity of another photodetector.

According to an embodiment, the first regions of the at least one diffractive structure of the resonant cavity of one of the photodetectors have lateral dimensions different from those of the first regions of the at least one diffractive structure of the resonant cavity of another photodetector.

According to an embodiment, within a same diffractive structure, one of the first regions has lateral dimensions different from those of another first region.

According to an embodiment, each first region is a pad.

According to an embodiment, each first region is a strip laterally extending between two opposite flanks of the diffractive structure.

According to an embodiment, the first regions form a grid and the second regions form pads located in boxes of the grid.

According to an embodiment, at least one of the resonant cavities has a thickness different from that of another resonant cavity.

According to an embodiment, the resonant cavity is formed of a stack comprising, in the order from an upper surface of the semiconductor substrate, the first mirror layer, the photoconversion layer, the diffractive structure, and the second mirror layer.

According to an embodiment, each resonant cavity further comprises at least one first insulating layer interposed between the at least one diffractive structure and the second mirror layer.

According to an embodiment, each resonant cavity further comprises at least one second insulating layer interposed between the photoconversion layer and the at least one diffractive structure.

According to an embodiment, the at least one photodetector is an infrared photodetector, preferably a near-infrared photodetector.

According to an embodiment, each pixel further comprises, stacked on said at least one photodetector, a visible photodetector.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 is a side and cross-section view, simplified and partial, of an example of an image sensor according to an embodiment;

FIG. 2 is a side and cross-section view, simplified and partial, of an example of an image sensor according to an embodiment;

FIG. 3 is a side and cross-section view, simplified and partial, of an example of an image sensor according to an embodiment;

FIG. 4 is a side and cross-section view, simplified and partial, of an example of an image sensor according to an embodiment;

FIG. 5 is a side and cross-section view, simplified and partial, of an example of an image sensor according to an embodiment;

FIG. 6 is a side and cross-section view, simplified and partial, of an example of an image sensor according to an embodiment;

FIG. 7 is a side and cross-section view, simplified and partial, of an example of an image sensor according to an embodiment;

FIG. 8 is a side and cross-section view, simplified and partial, of an example of an image sensor according to an embodiment;

FIG. 9 is a side and cross-section view, simplified and partial, of an example of an image sensor according to an embodiment; and

FIGS. 10A, 10B, 10C, 10D, and 10E illustrate, by side and cross-section views, simplified and partial, structures obtained at the end of successive steps of a method of manufacturing an example of an image sensor according to an embodiment.

### DESCRIPTION OF EMBODIMENTS

The same elements have been designated by the same references in the various figures. In particular, structural and/or functional elements common to the different embodiments may have the same references and may have identical structural, dimensional and material properties.

For the sake of clarity, only those steps and elements that are useful for understanding the described embodiments have been shown and are described in detail. In particular, the pixel control circuits of the image sensors have not been detailed, the implementation of these circuits being within the abilities of those skilled in the art based on the indications of the present disclosure. Further, the applications of image sensors comprising resonant optical cavity photodetectors have not been detailed, the described embodiments being compatible with all or most applications of such image sensors, subject to possible adaptations within the abilities of those skilled in the art upon reading of the present disclosure. As an example, the image sensors of the present disclosure may be implemented in 3D imaging applications, biomonitoring applications—for example, applications aiming at performing optical measurements of blood glucose levels—and in applications using an ambient light sensor (“ALS”)—for example, white balance (“WB”) adjustment applications.

Unless specified otherwise, when reference is made to elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as the terms “front”, “back”, “top”, “bottom”, “left”, “right”, etc., or relative position qualifiers, such as the terms “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of”signify plus or minus 10% or 10°, preferably of plus or minus 5% or 5°.

In the following description, the qualifiers “insulating” and “conductive” respectively signify, unless otherwise specified, electrically insulating and electrically conductive.

Unless otherwise specified, the expression “in contact with” signifies “in mechanical contact with.”

The expression “visible light” designates electromagnetic radiation having a wavelength in the range from 400 nm to 800 nm. The expression “infrared radiation” designates electromagnetic radiation having a wavelength in the range from 800 nm to 1 mm. In the infrared range, short-wave infrared (SWIR) radiation has a wavelength in the range from 800 nm to 1.7 μm.

The term “transmittance of a layer” designates a ratio of an intensity of a radiation leaving the layer to an intensity of the radiation entering the layer. In the rest of the disclosure, a layer is said to be opaque to a radiation when its transmittance is, for this radiation, smaller than 40%, preferably smaller than or equal to 25%, more preferably smaller than or equal to 10%. Further, a layer is said to be transparent to a radiation when its transmittance is, for this radiation, greater than or equal to 40%, preferably greater than or equal to 75%, and more preferably greater than or equal to 90%. The above definition of the qualifiers opaque and transparent is not limited to the case of a layer, but more generally applies to any element likely to be exposed to a radiation, for example, a substrate, a region, a stack of a plurality of layers, etc.

The expression “radiation of interest” designates a radiation having a wavelength substantially corresponding to a peak of maximum absorption of a photosensitive element, for example a photodetector of an image sensor pixel.

The expression “photoconversion layer” of an optoelectronic component, in particular of a photodetector, designates a layer in which most of the electromagnetic radiation received by the optoelectronic component is absorbed and in which this radiation is converted into electrical charges.

The refractive index of a material corresponds to the refractive index of the material for the wavelength range of the radiation captured by the image sensor. Unless otherwise specified, the refractive index is considered as substantially constant over the wavelength range of the useful radiation, for example equal to the average of the refractive index over the wavelength range of the radiation of interest detected by the image sensor.

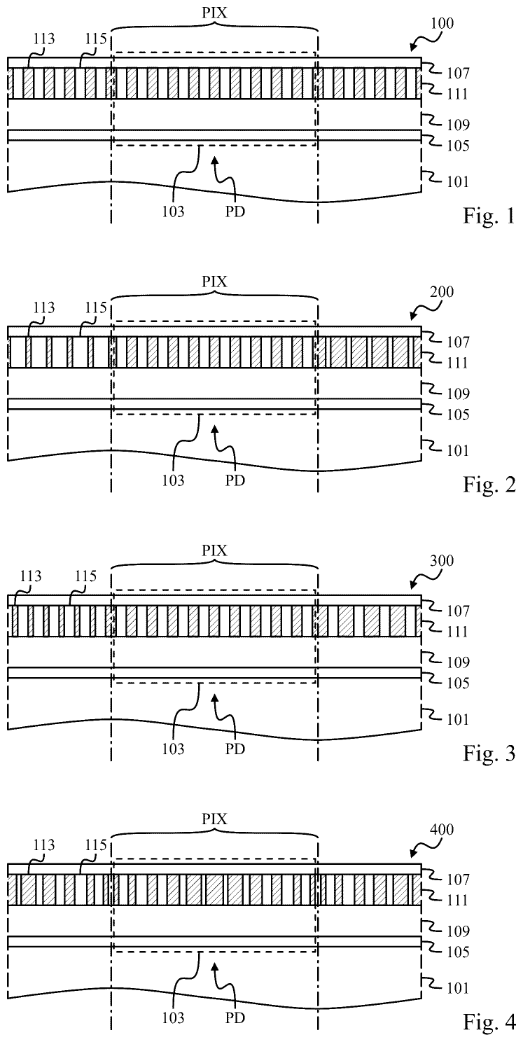

FIG. 1 is a side and cross-section view, simplified and partial, of an example of an image sensor 100 according to an embodiment.

In the shown example, image sensor 100 is intended to be illuminated or lit, from its upper surface, by an electromagnetic radiation comprising at least one radiation from among visible light and infrared radiation, for example near-infrared radiation.

In the shown example, image sensor 100 comprises a plurality of pixels PIX formed inside and on top of a semiconductor substrate 101, for example a wafer or piece of wafer made of a semiconductor material, for example silicon. Pixels PIX are, for example, arranged in an array of rows and columns. Each pixel PIX has, for example, in top view, a square shape. This example is however not limiting, and each pixel PIX may more generally have, in top view, any shape, for example a polygonal shape other than square—for example, rectangular, triangular, hexagonal, etc.—or a rounded shape—for example, oval, circular, etc. Although this has not been detailed in FIG. 1, the control and readout circuits of the pixels PIX of image sensor 100 are, for example, formed inside and on top of semiconductor substrate 101. Further, although only three pixels PIX have been shown in FIG. 1, image sensor 100 may of course comprise a much larger number of pixels PIX, for example several thousand or several million pixels PIX.

According to an embodiment, each pixel PIX of image sensor 100 comprises a photodetector PD comprising a resonant cavity 103 comprising, between first and second mirror layers 105 and 107, a photoconversion layer 109 and at least one diffractive structure 111. For simplification, the following description details a case in which each pixel PIX of image sensor 100 comprises a single photodetector PD. This example is however not limiting, and each pixel PIX of image sensor 100 may, as a variant, comprise any number greater than or equal to two, of photodetectors PD. The alternative embodiment in which each pixel PIX of image sensor 100 comprises at least two photodetectors PD is within the abilities of those skilled in the art based on the present disclosure.

As an example, the resonant cavities 103 of image sensor 100 are Fabry-Perot type cavities.

In the shown example, the first mirror layer 105, or first optically-reflective layer, coats the upper surface of semiconductor substrate 101. In this example, the first mirror layer 105 is more precisely located on top of and in contact with the upper surface of semiconductor substrate 101. The first mirror layer 105 has, for example, a single-layer structure. In this case, the first mirror layer 105 is, for example, a metal layer, that is, a layer made of a metal or of a metallic alloy, or a layer made of a heavily-doped semiconductor material, for example doped silicon. As a variant, the first mirror layer 105 may have a multilayer structure. In this case, the first mirror layer 105 is, for example, a Bragg mirror formed of a stack of layers having alternating refractive indices.

In the shown example, photoconversion layer 109, also called photosensitive layer or active layer, coats the upper surface of the first mirror layer 105. In this example, photoconversion layer 109 is located on top of and in contact with the upper surface of the first mirror layer 105. Photoconversion layer 109 is, for example, an optically-absorbing layer intended to absorb, or to capture, the radiation illuminating image sensor 100 and to convert photons of this radiation into electron-hole pairs. Photoconversion layer 109 is, for example, an inorganic semiconductor layer, for example made of silicon in a case where image sensor 100 is a visible or near-infrared sensor. This example is however not limiting, and photoconversion layer 109 may, as a variant, be made of at least one semiconductor material of the IV family, for example of germanium, of silicon-germanium, of germanium-tin, etc.

Further, photoconversion layer 109 may incorporate a superlattice, quantum dots, for example based on lead sulphide or on indium arsenide, on III-V semiconductor materials, for example InGaAs and its derivatives, on II-VI semiconductor materials, for example HgCdTe, etc. It may also be layers of organic materials such as PEDOT: PSS or a material from the perovskite family. As an example, photoconversion layer 109 has a thickness generally in the range from λ/6 to λ/4, where λ is the wavelength of the incident radiation. In the case of near-infrared, this corresponds to a thickness in the range from 200 to 400 nm, for example equal to approximately 250 nm.

In the illustrated example, diffractive structure 111 coats the upper surface of photoconversion layer 109. In this example, diffractive structure 111 is more precisely located on top of and in contact with the upper surface of photoconversion layer 109.

Generally, diffractive structure 111 comprises a plurality of first regions 113 made of a first material having a first refractive index n1, the first regions 113 being disjoint and laterally separated from each other by at least one second region 115 made of a second material having a second refractive index n2, different from the first refractive index n1. The first regions 113 have at least one lateral dimension smaller than a wavelength of a radiation of interest intended to illuminate image sensor 100. As an example, the first and second materials have different chemical compositions. As a variant, the first and second materials may have identical chemical compositions and differ in their structure, one of the materials corresponding, for example, to an amorphous phase of a phase-change material, for example, a chalcogenide material such as GST, Sb₂S₃, Sb₂Se₃, etc., the other material corresponding to the crystalline phase of this material.

The first and second materials are, for example, selected so that they have the greatest possible refractive index contrast or, in other words, so that the difference between the first and second refractive indices n1 and n2 is as large as possible. The first refractive index n1 is, for example, greater than the second refractive index n2. Further, the first, and second materials have, for example, at the wavelength of the radiation of interest, a substantially zero extinction coefficient. As an example, each first region 113 is made of silicon and each second region 115 is made of silicon oxide. In the case of a detection in the visible range, each first region 113 may, as a variant, be made of a metal oxide such as HfO₂, Nb₂O₅, or TiO₂. It may also be, for example, GaP or any other material having a high refractive index and a low extinction coefficient for the spectral band of interest. This example is however not limiting, and each second region 115 may, as a variant, be made of an air-filled cavity or of a cavity in which partial vacuum prevails.

In the shown example, the first regions 113 have a same height, or thickness, that is, a same dimension in a direction orthogonal to the first and second mirror layers 105 and 107.

In this example, the second regions 115 also have a same height, or thickness, for example a height substantially equal to that of the first regions 113.

Each first region 113 is, for example, a pad. In this case, diffractive structure 111 comprises, for example, a single second region 115 coating the side walls, or flanks, of the first regions 113. As an example, the second region 115 completely fills all the free spaces laterally extending between the first regions 113. In this example, the second region 115 is located on top of and in contact with all the side walls of the first regions 113. Each pad has, for example, in top view, a rectangular or square cross-section. This example is however not limiting, and each pad may more generally have, in top view, a cross-section of any shape, for example a polygonal cross-section other than square or rectangular—for example triangular, hexagonal, etc.—or a rounded cross-section—for example oval, circular, etc. In the case where each first region 113 is a pad of rectangular, square, or circular cross-section, the width, the side length, or the diameter, respectively, of the pad is, for example, smaller than the wavelength of the radiation of interest, for example at least from two to ten times smaller than the wavelength of the radiation of interest.

As a variant, each first region 113 may have the form of a strip laterally extending along a direction parallel to the upper surface of photoconversion layer 109, for example a direction substantially orthogonal to the cross-section plane of FIG. 1, between two opposite flanks of diffractive structure 111. Each strip has, for example, in top view, a rectangular shape. In this variant, the diffractive structure comprises, for example, a plurality of second regions 115, each second region 115 then being laterally interposed between two neighboring first regions 113. As an example, each second region 115 completely fills all the free spaces laterally extending between two neighboring first regions 113. In this example, each second region 115 is located on top of and in contact with the side walls of the neighboring first regions 113 located opposite each other. In the case where each first region 113 is a rectangular strip, the width of each strip is, for example, smaller than the wavelength of the radiation of interest.

As a variant, the first regions 113 may form a grid, each second region 115 then being in the form of a pad located in one of the boxes of the grid. As a variant, the first and second regions 113 and 115 may have a “free-form” shape, that is, regions 113 and 115 do not have in this case any defined and repeatable shape and/or dimensions and/or symmetry from one pixel PIX to the other.

Each first region 113 corresponds, for example, to a unit element of diffractive structure 111. Diffractive structure 111 is, for example, a metasurface. Each first region 113 corresponds, for example, to a meta-atom of the metasurface.

As an example, the diffractive structure may be designed to form a resonant waveguide grating (RWG) or guided mode resonant filter.

Diffractive structure 111 may have a resonance frequency which depends on several parameters, including: the lateral dimensions of the first regions 113, the refractive indices n1 and n2 of the first and second regions 113 and 115, and the spatial distribution of the first and second regions 113 and 115. By modifying these parameters, it is thus possible to control the resonance frequency of diffractive structure 111, for example so that the resonance frequency corresponds to a wavelength which is desired to be detected by means of photodetectors PD. As compared with the use of color filters or with the use of cavities similar to cavities 103 but without diffractive structure 111, the use of diffractive structure 111 enables to obtain a better selectivity in terms of wavelengths.

In the shown example, the second mirror layer 107, or second optically-reflective layer, coats the upper surface of diffractive structure 111. In this example, the second mirror layer 107 is more precisely located on top of and in contact with the upper surface of diffractive structure 111. The second mirror layer 107 is, for example, similar or identical to the first mirror layer 105.

Each photodetector PD thus comprises a vertical stack comprising, in the order from the upper surface of substrate 101, the first mirror layer 105, photoconversion layer 109, diffractive structure 111, and the second mirror layer 107. In the example illustrated in FIG. 1, the stack is more specifically formed, in the order from the upper surface of substrate 101, of the first mirror layer 105, of photoconversion layer 109, of diffractive structure 111, and of the second mirror layer 107.

The first and second mirror layers 105 and 107 are intended to confine, within resonant cavity 103, the incident radiation illuminating image sensor 100. When this radiation reaches the upper surface of image sensor 100, it passes through the second mirror layer 107, diffractive structure 111, and photoconversion layer 109. As it passes through photoconversion layer 109, some of the photons of the radiation are absorbed and converted into electron-hole pairs. The remaining photons, that is, the photons which have not been absorbed by photoconversion layer 109, reach the upper surface of the first mirror layer 105 and are then reflected or sent back, upwards, towards the second mirror layer 107. Some photons are here again absorbed and converted into electron-hole pairs by photoconversion layer 109, while the other photons pass through photoconversion layer 109 and diffractive structure 111. These photons reach the lower surface of the second mirror layer 107, which reflects them or sends them back, downwards, towards the first mirror layer 105.

Photons having a wavelength compatible with, or selected by, resonant cavity 103 can thus travel back and forth several times inside resonant cavity 103 before being absorbed by photoconversion layer 109, which improves the absorption efficiency for this wavelength.

Photoconversion layer 109 mainly absorbs the photons of the radiation having a wavelength substantially corresponding to the resonance frequency of the resonant cavity associated with diffractive structure 111. This enables the photodetectors PD of the pixels PIX of the image sensor 100 of FIG. 1 to have a higher efficiency or photoconversion rate than that of similar photodetectors PD but without optically-resonant cavities 103 or, to provide, for a same photoconversion rate, a photoconversion layer 109 of smaller thickness.

FIG. 1 illustrates an embodiment in which the first regions 113 of the diffractive structures 111 of all the photodetectors PD of image sensor 100 have substantially identical lateral dimensions. Further, in this embodiment, the first regions 113 form a grating having a substantially constant pitch. In the case where each first region 113 is a pad, the pitch of the grating corresponds, for example, to a center-to-center distance between two neighboring pads. In the case where each first region 113 is a strip, the pitch of the grating corresponds, for example, to a distance between two median lines of two neighboring strips. More precisely, in this case, the first regions 113 have, within the diffractive structure 111 of the same pixel PIX, identical lateral dimensions and a substantially constant pitch. Further, in the embodiment of FIG. 1, the first regions 113 of the diffractive structure 111 of each photodetector PD have lateral dimensions and a pitch substantially identical to the lateral dimensions and to the pitch of the first regions 113 of the diffractive structures 111 of the other photodetectors PD of image sensor 100.

Diffractive structures 111 may enable image sensor 100 to have better angular tolerance than an image sensor without diffractive structures 111.

Although this has not been shown in FIG. 1 in order not to overload the drawing, a peripheral insulating trench may be formed around the resonant cavity 103 of each photodetector PD of image sensor 100. In this case, the trench extends, for example, vertically from the upper surface of resonant cavity 103 along all or part of the height of the resonant cavity 103 of photodetector PD. For example, the insulating trench may comprise a central region made of a conductive material, for example, a metal, a metal alloy, or a doped semiconductor material, surrounded by a peripheral insulating region, for example made of an oxide. As a variant, the central region is made of a material having a low refractive index, for example lower than that of photoconversion layer 109.

FIG. 2 is a side and cross-section view, simplified and partial, of an example of an image sensor 200 according to an embodiment.

The image sensor 200 of FIG. 2 has features in common with the image sensor 100 of FIG. 1. These common features will not be described in detail hereafter.

The image sensor 200 of FIG. 2 differs from the image sensor 100 of FIG. 1 in that the diffractive structures 111 of the photodetectors PD of the pixels PIX of the image sensor 200 of FIG. 2 have different fill factors. The fill factor of each diffractive structure 111 corresponds to the ratio of, on the one hand, the cumulative surface area, in top view, of the first regions 113 to, on the other hand, the surface area of the second region 115 or the cumulative area of the second regions 115, in top view, of diffractive structure 111.

In the illustrated example, the first regions 113 of diffractive structures 111 form a grating having a substantially constant pitch over the entire image sensor 200. In this example, the first regions 113 of the diffractive structure 111 of one of the photodetectors PD (for example, the diffractive structure 111 of the photodetector PD of the central pixel PIX, in the orientation of FIG. 2) have lateral dimensions different from those of the first regions 113 of the diffractive structure 111 of one of the other photodetectors PD of image sensor 200 (for example, the diffractive structure 111 of the photodetector PD of the left-hand pixel PIX, in the orientation of FIG. 2).

The wavelength range absorbed by each resonant cavity 103 is a function, apart from a thickness of cavity 103, of the fill factor of diffractive structure 111. In a case where the diffractive structure is periodic and symmetrical, the higher the fill factor of diffractive structure 111, the higher the wavelength of the radiation predominantly absorbed by the corresponding pixel PIX, at a constant grating pitch. However, in practice, it is possible for diffractive structure 111 not to be periodic and/or symmetrical, for example because the optimization of this structure takes into account other parameters than the wavelength of interest, such as the angular tolerance to the angle of incidence, the optical crosstalk between pixels, the position of the pixel relative to the matrix, etc. Each resonant cavity 103 has an effective optical index depending on the material of the first regions 113, this material being, for example, identical for all the cavities 103 of image sensor 200, on the fill factor, on the pitch of diffractive structure 111 and, at the second order, on the geometry of the regions 113 and 115 of the diffractive structure 111 of the considered resonant cavity 103. As a first approximation, the fact of providing resonant cavities 103 having diffractive structures 111 exhibiting different fill factors enables to obtain different optical indices inside these cavities, and thus to absorb the incident radiation in different wavelength ranges.

Further, the fact of providing, as in the example illustrated in FIG. 2, groups of adjacent resonant cavities 103 of the same thickness but with diffractive structures having, within a same group, different fill factors, enables image sensor 200 to benefit from a higher spatial resolution than that which would for example be exhibited by the image sensor 200 without diffractive structures 111.

As an example, image sensor 200 is a multispectral sensor.

FIG. 3 is a side and cross-section view, simplified and partial, of an example of an image sensor 300 according to an embodiment.

The image sensor 300 of FIG. 3 has features in common with the image sensor 100 of FIG. 1. These common features will not be described in detail hereafter.

The image sensor 300 of FIG. 3 differs from the image sensor 100 of FIG. 1 in that the diffractive structures 111 of the photodetectors PD of the pixels PIX of the image sensor 300 of FIG. 3 have different fill factors. In the shown example, the first regions 113 of the diffractive structures 111 have different lateral dimensions from one photodetector PD to the other and a substantially constant spacing. In this example, the first regions 113 of the diffractive structure 111 of one of photodetectors PD (for example, the diffractive structure 111 of the photodetector PD of the central pixel PIX, in the orientation of FIG. 3) have lateral dimensions different from those of the first regions 113 of the diffractive structure 111 of one of the other photodetectors PD of image sensor 300 (for example, the diffractive structure 111 of the photodetector PD of the left-hand pixel PIX, in the orientation of FIG. 3).

FIG. 2 illustrates a case in which different fill factors of the diffractive structures 111 are obtained by changing the lateral dimensions of the first regions 113 without changing the pitch of the grating formed by the first regions 113. Further, FIG. 3 illustrates a case in which different fill factors of the diffractive structures 111 are obtained by modifying the lateral dimensions of the first regions 113 and by modifying the pitch of the grating formed by the first regions 113. These examples are however not limiting, and those skilled in the art are capable, as a variant, of providing other means enabling to obtain different fill factors of diffractive structures 111, for example by modifying the pitch of the grating formed by the first regions 113 without modifying the lateral dimensions of the first regions 113. Other means enabling to modify the resonance wavelength have further been described above.

FIG. 4 is a side and cross-section view, simplified and partial, of an example of an image sensor 400 according to an embodiment.

The image sensor 400 of FIG. 4 has features in common with the image sensor 100 of FIG. 1. These common features will not be described again hereafter.

The image sensor 400 of FIG. 4 differs from the image sensor 100 of FIG. 1 in that the first regions 113 of the diffractive structures 111 of the photodetectors PD of the pixels PIX of the image sensor 400 of FIG. 4 have, within a same diffractive structure 111, different lateral dimensions. In the shown example, the first regions 113 belonging to a same diffractive structure 111 of a same pixel PIX form a grating having a substantially constant pitch. Further, in this example, the first regions 113 of the diffractive structures 111 of the photodetectors PD of all the pixels PIX of image sensor 400 form a grating having a substantially constant pitch. This example is however not limiting, and those skilled in the art may, as a variant or as a complement, provide for the first regions 113 of the diffractive structure 111 of the photodetector PD of at least one of the pixels PIX of image sensor 400 to form a grating having a different pitch than that formed by the first regions 113 of the diffractive structure 111 of the photodetector PD of the other pixels PIX of image sensor 400.

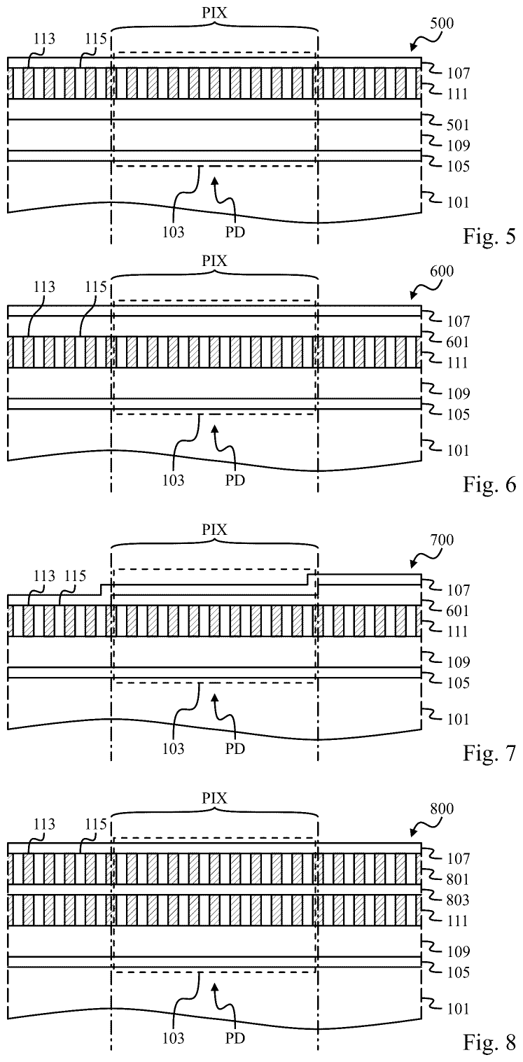

FIG. 5 is a side and cross-section view, simplified and partial, of an example of an image sensor 500 according to an embodiment.

The image sensor 500 of FIG. 5 has features in common with the image sensor 100 of FIG. 1. These common features will not be described in detail again hereafter.

The image sensor 500 of FIG. 5 differs from the image sensor 100 of FIG. 1 in that each resonant cavity 103 of the image sensor 500 of FIG. 5 further comprises an insulating layer 501 interposed between photoconversion layer 109 and diffractive structure 111. In the shown example, insulating layer 501 is located on top of and in contact, by its lower surface, with the upper surface of photoconversion layer 109. Further, in this example, insulating layer 501 is located under and in contact, by its upper surface, with the lower surface of diffractive structure 111. In the shown example, insulating layer 501 has a substantially constant thickness. Insulating layer 501 is a layer transparent to the radiation of interest of image sensor 500. As an example, insulating layer 501 is made of an oxide, for example silicon oxide. Insulating layer 501 may have a single-layer or multi-layer structure, for example a structure comprising a plurality of layers, for example two layers, made of transparent materials having different refractive indices and exhibiting a high refractive index contrast, that is, a large difference in refractive indices.

As an example, insulating layer 501 is used as a waveguide, for example in the case where diffractive structure 111 forms a guided mode resonant filter. In this case, one or more layers having optical indices and thicknesses optically coupled to diffractive structure 111 in order to guide light and induce resonances may more generally be provided. Further, the presence of insulating layer 501 increases the optical path of light in the cavity, which is another way of adapting the resonance wavelength of the filter.

FIG. 6 is a side and cross-section view, simplified and partial, of an example of an image sensor 600 according to an embodiment.

The image sensor 600 of FIG. 6 has features in common with the image sensor 100 of FIG. 1. These common features will not be described in detail hereafter.

The image sensor 600 of FIG. 6 differs from the image sensor 100 of FIG. 1 in that each resonant cavity 103 of the image sensor of FIG. 6 further comprises an insulating layer 601 interposed between diffractive structure 111 and the second mirror layer 107. In the shown example, insulating layer 601 is located on top of and in contact, by its lower surface, with the upper surface of diffractive structure 111. Further, in this example, insulating layer 601 is located under and in contact, by its upper surface, with the lower surface of the second mirror layer 107. In the shown example, insulating layer 601 has a substantially constant thickness. Insulating layer 601 is a layer transparent to the radiation of interest of image sensor 600. As an example, insulating layer 601 is made of an oxide, for example silicon oxide. Insulating layer 601 may have a single-layer or multi-layer structure, for example a structure comprising a plurality of layers, for example two layers, made of transparent materials having different optical indices and exhibiting a high optical index contrast.

Insulating layer 601 is, for example, similar to insulating layer 501.

FIG. 7 is a side and cross-section view, simplified and partial, of an example of an image sensor 700 according to an embodiment.

The image sensor 700 of FIG. 7 has features in common with the image sensor 600 of FIG. 6. These common features will not be described in detail hereafter.

The image sensor 700 of FIG. 7 differs from the image sensor 600 of FIG. 6 in that the insulating layer 601 of image sensor 700, interposed between diffractive structure 111 and the second mirror layer 107, has a variable thickness. In the shown example, the insulating layer 601 of the resonant cavity 103 of the photodetector PD of one of the pixels PIX of image sensor 700 (for example, the insulating layer 601 of the cavity 103 of the central pixel PIX, in the orientation of FIG. 7) has a thickness different from that of the insulating layer 601 of the resonant cavity 103 of the photodetector PD of one of the other pixels PIX of image sensor 700 (for example, the insulating layer 601 of the cavity 103 of the left-hand pixel PIX, in the orientation of FIG. 7). Thus, conversely to the image sensors 100, 200, 300, 400, 500, and 600 described hereabove in relation with FIGS. 1 to 6, the image sensor 700 of FIG. 7 comprises at least one resonant cavity 103 having a height, or thickness, different from those of the other cavities 103.

The presence of resonant cavities 103 of different thicknesses enables image sensor 700 to access a wider spectral band than that which would be obtained by means of resonant cavities 103 only differing by the fill factors of their diffractive structures 111. Further, the presence of diffractive structures 111 having different fill factors enables image sensor 700 to have a higher spectral resolution than that which would be obtained by means of a filter only comprising resonant cavities 103 having different thicknesses, for example due to limitations inherent to methods of forming cavities of variable thicknesses.

Thus, the fact of combining, in image sensor 700, resonant cavities 103 having different thicknesses and, inside the cavities, diffractive structures 111 having different fill factors enables to achieve a broader spectral band or a higher resolution than that of an image sensor having only one of these characteristics.

FIG. 8 is a side and cross-section view, simplified and partial, of an example of an image sensor 800 according to an embodiment.

The image sensor 800 of FIG. 8 has features in common with the image sensor 100 of FIG. 1. These common features will not be described in detail hereafter.

The image sensor 800 of FIG. 8 differs from the image sensor 100 of FIG. 1 in that each resonant cavity 103 of the image sensor 800 of FIG. 8 comprises another diffractive structure 801 interposed between the first and second mirror layers 105 and 107. In the shown example, each resonant cavity 103 further comprises an insulating layer 803 interposed between diffractive structures 111 and 801. As a variant, layer 803 is omitted. In the shown example, insulating layer 803 is located on top of and in contact, by its lower surface, with the upper surface of diffractive structure 111. Further, in this example, insulating layer 803 is located under and in contact, by its upper surface, with the lower surface of diffractive structure 801. In the shown example, diffractive structure 801 is located under and in contact, via its upper surface, with the lower surface of second mirror layer 107. In the shown example, insulating layer 803 has a substantially constant thickness. Insulating layer 803 is a layer transparent to the radiation of interest of image sensor 800. As an example, insulating layer 803 is made of an oxide, for example silicon oxide.

As an example, diffractive structure 801 is similar or identical to diffractive structure 111. In the case where diffractive structures 801 and 111 are identical, to within manufacturing dispersions, this enables, for example, to increase the thickness of image sensor 800. As a variant, diffractive structure 801 is different from diffractive structure 111. This provides, for example, a greater freedom in the design and implementation of image sensor 800.

The image sensor 800 has, for example, due to the fact that it comprises diffractive structure 801, a higher spatial resolution than that of image sensor 100.

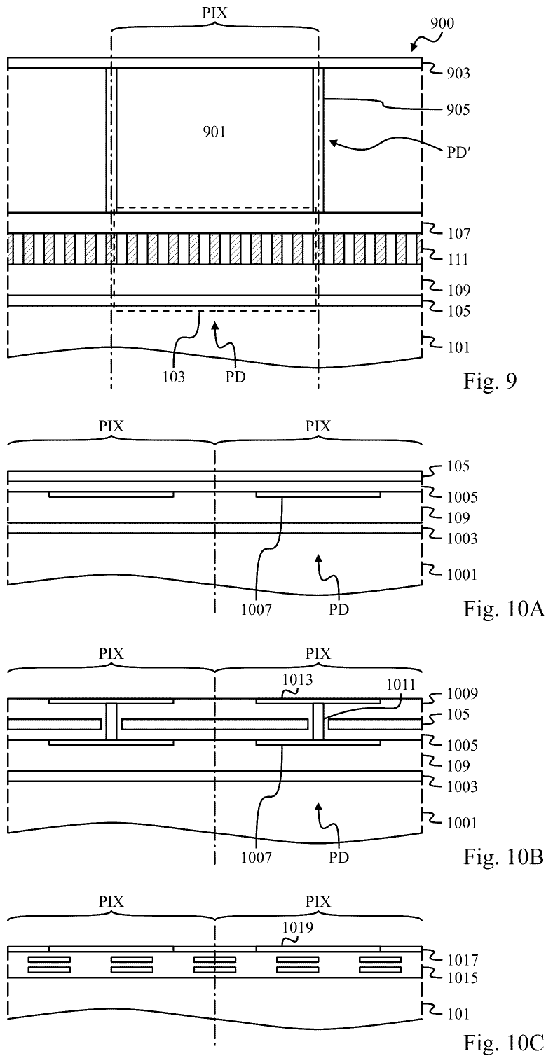

FIG. 9 is a side and cross-section view, simplified and partial, of an example of an image sensor 900 according to an embodiment.

The image sensor 900 in FIG. 9 has features in common with the image sensor 100 of FIG. 1. These common features will not be described in detail hereafter.

The image sensor 900 of FIG. 9 differs from the image sensor 100 of FIG. 1 in that each pixel PIX of the image sensor 900 of FIG. 9 further comprises another photodetector PD′ located on top of and vertically in line with the photodetector PD formed in resonant cavity 103. Photodetector PD′ is, for example, sensitive in a wavelength range different from the sensitivity range of photodetector PD. Photodetector PD′ is, for example, a visible photodetector, that is, intended to detect visible light and to convert this light into electron-hole pairs. In the shown example, the second mirror layer 107 is, for example, a layer of an oxide, for example silicon oxide, interposed between photodetectors PD and PD′. As an example, the second mirror layer 107 is formed during a step of transfer, for example by molecular bonding, of the visible photodetectors PD′ onto photodetectors PD.

In the shown example, each visible photodetector PD′ comprises a photoconversion layer 901, also called active layer or photosensitive layer, interposed between the second mirror layer 107 and an insulating layer 903. In this example, photoconversion layer 901 is located on top of and in contact, by its lower surface, with the upper surface of the second mirror layer 107 and under and in contact, by its upper surface, with the lower surface of insulating layer 903. Insulating layer 903 is a layer transparent to the radiation of interest of image sensor 900. For example, insulating layer 903 is made of an oxide, for example silicon oxide. Insulating layer 903 may have a single-layer or multi-layer structure, for example a structure comprising a stack of layers made of insulating materials selected from among silicon oxide, silicon nitride, silicon oxynitride, etc. Insulating layer 903 has, for example, the function of passivating the sensor.

In the shown example, the photoconversion layer 901 of each visible photodetector PD′ is laterally bordered by an insulating trench 905. In this example, insulating trench 905 coats the sides of photoconversion layer 901. Insulating trench 905 is, for example, more precisely located on top of and in contact with all the sides of photoconversion layer 901.

Although this has not been shown in FIG. 9, image sensor 900 may further comprise color filters and microlenses covering the upper surface of insulating layer 903. In this case, the color filters of image sensor 900 are, for example, red, green, and blue filters arranged in the form of a matrix, for example a Bayer matrix.

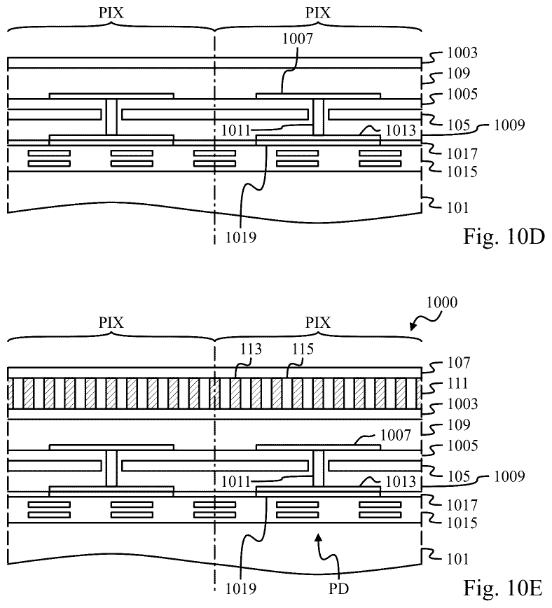

FIG. 10A, FIG. 10B, FIG. 10C, FIG. 10D, and FIG. 10E show, in side and cross-section views, simplified, and partial, structures obtained at the end of successive steps of a method of manufacturing an image sensor 1000 according to an embodiment. Image sensor 1000 comprises features in common with the image sensor 100 of FIG. 1. These common features will not be described again hereafter.

For simplification, only two pixels PIX, each comprising a single photodetector PD, have been illustrated in FIGS. 10A to 10E, it being understood that image sensor 1000 may, as a variant, comprise a larger number of pixels PIX and that each pixel PIX may comprise a plurality of photodetectors PD.

FIG. 10A illustrates a structure obtained at the end of a step of forming, on a temporary support substrate 1001, or handle, of a stack comprising, in this order from the upper surface of temporary support substrate 1001, an insulating layer 1003, photoconversion layer 109, an insulating layer 1005, and the first mirror layer 105.

In the shown example, each photodetector PD comprises a doped region 1007 enabling to form a semiconductor junction within layer 109, thereby enabling to extract photogenerated charges. Doped region 1007 extends in photoconversion layer 109 from the upper surface of layer 109 down to a depth smaller than the thickness of layer 109. As an example, conductive region 1007 corresponds to an area of photoconversion layer 109 having a doping level greater than, for example at least ten, one hundred, or one thousand times greater than that of the rest of photoconversion layer 109. Doped region 1007 acts, for example, as the lower electrode of photodetector PD and is insulated from the doped regions 1007 of the other photodetectors PD of image sensor 1000.

Although this has not been illustrated in FIG. 10A in order not to overload the drawing, a portion of the photoconversion layer 109 located on top of and in contact with the underlying insulating layer 1003 may, for each photodetector PD of image sensor 1000, be doped to form another electrode of photodetector 1000. Unlike doped regions 1007, this electrode may be common to a plurality of photodetectors PD, or even to all the photodetectors PD, of image sensor 1000.

FIG. 10B illustrates a structure obtained at the end of a subsequent step of deposition of an insulating layer 1009 on the upper surface of the structure of FIG. 10A, of opening of insulating layer 1009 and of mirror layer 105 vertically in line with doped regions 1007, of forming of conductive vias 1011 in the openings, and of forming of contacting elements 1013 in insulating layer 1009.

Insulating layer 1009 coats mirror layer 105. In the shown example, insulating layer 1009 is more specifically located on top of and in contact with mirror layer 105. As an example, insulating layer 1009 is made of an oxide, for example silicon oxide.

In the shown example, contacting elements 1013 extend in insulating layer 1009 from the upper surface of layer 1009 down to a depth smaller than the thickness of layer 1009.

Each contacting element 1013 is, for example, located vertically in line with a doped region 1007. As an example, contacting elements 1013 are made of a metal or of a metal alloy.

Contacting elements 1013 are, for example, formed by the implementation of a “damascene” type process.

In the shown example, each conductive via 1011 extends from the lower surface of one of contacting elements 1013 through insulating layer 1009, mirror layer 105, and insulating layer 1005 all the way to the upper surface of the underlying doped region 1007.

As an example, each conductive via 1011 has a conductive central region having its sides coated with an insulating region, for example made of an oxide, for example silicon oxide.

This particularly enables to insulate the central region of via 1011 from mirror layer 105. In practice, first holes are for example formed in layer 105, then filled with oxide, and second holes having lateral dimensions smaller than the first holes are then formed in the oxide.

FIG. 10C illustrates a structure obtained at the end of a step of forming, on semiconductor substrate 101, of an interconnection stack 1015 and of an insulating layer 1017 in which contacting elements 1019 are formed. The structure shown in FIG. 10C may indifferently be formed before, during, or after the structure previously described in relation with FIGS. 10A and 10B.

As an example, semiconductor substrate 101 is of CMOS (“Complementary Metal-Oxide-Semiconductor”) type and comprises CMOS control transistors for the pixels PIX of image sensor 1000.

Interconnection stack 1015 coats, for example, the upper surface of semiconductor substrate 101. In the shown example, interconnection stack 1015 is more specifically located on top of and in contact with the upper surface of semiconductor substrate 101. For example, interconnection stack 1015 comprises conductive layers, for example metal layers, also called metallization levels, and alternating insulating layers. Interconnection stack 1015 enables, for example, to connect contacting elements 1019 to the transistors formed in semiconductor substrate 101.

In the shown example, insulating layer 1017 coats the upper surface of interconnection stack 1015. As a variant, insulating layer 1017 may form part of interconnection stack 1015.

In the shown example, contacting elements 1019 each have a height substantially equal to the thickness of insulating layer 1017. Each contacting element 1019 is, for example, intended to be brought into contact with one of contact recovery elements 1013. For example, contact recovery elements 1019 are made of a metal or a metal alloy. Contact recovery elements 1019 are, for example, formed by the implementation of a “damascene” type process.

FIG. 10D illustrates a structure obtained at the end of a subsequent step of transfer of the structure of FIG. 10B onto the structure of FIG. 10C and of removal of temporary support substrate 1001.

The structure of FIG. 10B is, for example, turned over and then brought into contact, by surfaces of insulating layer 1009 and of contacting elements 1013 opposite to temporary support substrate 1001 (the lower surfaces of insulating layer 1009 and of contacting elements 1013, in the orientation of FIG. 10D), with the upper surfaces of the insulating layer 1017 and of the contacting elements 1019 of the structure of FIG. 10C, respectively. As an example, the structures are mechanically joined, that is, mechanically attached to each other, by bonding of the surfaces in contact. The bonding is, for example, a bonding of direct type, for example, a molecular bonding. In the case where insulating regions 1009 and 1017 are made of oxide and where contacting elements 1013 and 1019 are metallic, the molecular bonding is said to be “hybrid”.

The removal of temporary support substrate 1001 is for example performed by chemical and mechanical polishing (CMP). In the shown example, temporary support substrate 1001 is fully removed at the end of this step.

At the end of this step, doped regions 1007 are, for example, connected to the control transistors of the pixels PIX formed in semiconductor substrate 101.

FIG. 10E illustrates a structure obtained at the end of a subsequent step of forming of diffractive structures 111 and then of second mirror layer 107 on the side of the upper surface of the structure of FIG. 10D.

Diffractive structures 111 are, for example, formed by deposition of a first layer made of the first material of the first regions 113, followed by a step of photolithography and then etching of the first layer so as to form through openings in the first layer. The openings formed in the first layer are then filled, for example, by the deposition of a second layer of the second material of the second region(s) 115. A mechanical-chemical polishing operation may be carried out subsequently to the deposition of the second layer so that the upper surface of each diffractive structure 111 has a substantially planar surface.

Mirror layer 107 is then for example deposited on diffractive structure 111.

Various embodiments and variants have been described. Those skilled in the art will understand that certain features of these various embodiments and variants may be combined, and other variants will occur to those skilled in the art. In particular, those skilled in the art are capable of performing combinations between the embodiments of FIGS. 1 to 9 and 10E. Further, those skilled in the art are capable of adapting the method described in relation with FIGS. 10A to 10E to form the image sensors previously described in relation with FIGS. 2 to 9 based on the indications of the present description.

Finally, the practical implementation of the described embodiments and variants is within the abilities of those skilled in the art based on the functional indications given hereabove. In particular, the described embodiments are not limited to the specific examples of materials and of dimensions mentioned in the present disclosure.

1. Image sensor comprising a plurality of pixels formed inside and on top of a semiconductor substrate and each comprising at least one photodetector comprising a resonant cavity comprising, between first and second mirror layers, a photoconversion layer and at least one diffractive structure.

2. Sensor according to claim 1, wherein each diffractive structure comprises a plurality of first regions made of a first material having a first refractive index separated from one another by at least one second region made of a second material having a second refractive index lower than the first refractive index.

3. Sensor according to claim 2, wherein the first and second materials have a same chemical composition and different structures.

4. Sensor according to claim 2, wherein the diffractive structures of the resonant cavities of the photodetectors have a same fill factor.

5. Sensor according to claim 2, wherein said at least one diffractive structure of the resonant cavity of one of the photodetectors has a fill factor different from that of said at least one diffractive structure of the resonant cavity of another photodetector.

6. Sensor according to claim 5, wherein the first regions of said at least one diffractive structure of the resonant cavity of one of the photodetectors form a grating having a pitch different from that of a grating formed by the first regions of the at least one diffractive structure of the resonant cavity of another photodetector.

7. Sensor according to claim 5, wherein the first regions of said at least one diffractive structure of the resonant cavity of one of the photodetectors have lateral dimensions different from those of the first regions of said at least one diffractive structure of the resonant cavity of another photodetector.

8. Sensor according to claim 4, wherein, within a same diffractive structure, one of the first regions has lateral dimensions different from those of another first region.

9. Sensor according to claim 3, wherein each first region is a pad.

10. Sensor according to claim 3, wherein each first region is a strip laterally extending between two opposite flanks of the diffractive structure.

11. Sensor according to claim 3, wherein the first regions form a grid and the second regions form pads located in boxes of the grid.

12. Sensor according to claim 1, wherein at least one of the resonant cavities has a thickness different from that of another resonant cavity.

13. Sensor according to claim 1, wherein the resonant cavity is formed of a stack comprising, in the order from an upper surface of the semiconductor substrate, the first mirror layer, the photoconversion layer, the diffractive structure, and the second mirror layer.

14. Sensor according to claim 1, wherein each resonant cavity further comprises at least one insulating layer interposed between said at least one diffractive structure and the second mirror layer.

15. Sensor according to claim 1, wherein each resonant cavity further comprises at least one second insulating layer interposed between the photoconversion layer and said at least one diffractive structure.

16. Sensor according to claim 1, wherein said at least one photodetector is an infrared photodetector, preferably a near-infrared photodetector.

17. Sensor according to claim 1, wherein each pixel further comprises, stacked on said at least one photodetector, a visible photodetector.
